(19) United States
(12) Patent Application Publication
(10) Pub. No.: US 2008/0242086 A1
(43) Pub. Date: Oct. 2, 2008

(54) PLASMA PROCESSING METHOD AND PLASMA PROCESSING APPARATUS

(75) Inventors: Hiroki MATSUMARU, Sendai City (JP); Nobutaka Nakao, Nirasaki-shi (JP); Kenji Komatsu, Nirasaki-shi (JP); Syuichi Takahashi, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/057,518

(22) Filed: Mar. 28, 2008

Related U.S. Application Data
(60) Provisional application No. 60/941,774, filed on Jun. 4, 2007.

(30) Foreign Application Priority Data
Mar. 29, 2007 (JP) 2007-088664

(51) Int. Cl. H01L 21/44

(52) U.S. Cl. 438/680; 257/E21.476

(57) ABSTRACT

A plasma processing method, for performing a plasma process on a target substrate by generating a plasma between an upper electrode and a lower electrode facing each other by means of applying a radio frequency power therebetween, includes applying a DC voltage of a positive or negative polarity to an inner electrode of an electrostatic chuck on the lower electrode to attract and hold the target substrate thereon; and changing the positive or negative polarity of the DC voltage applied to the inner electrode of the electrostatic chuck to an opposite polarity thereto between a time when the application of the radio frequency power from the radio frequency power supply is started to perform the plasma process of the target substrate and a time when the plasma process is completed.

### FIELD OF THE INVENTION

The present invention relates to a plasma processing method and apparatus for performing a plasma etching process or a film forming process on a target substrate such as a semiconductor wafer or an LCD (Liquid Crystal Display) substrate.

### BACKGROUND OF THE INVENTION

In a manufacturing process of semiconductor devices, various processes such as a film forming process, an annealing process, an etching process, an oxidation/diffusion process, and the like are performed. Most of these processes tend to be implemented by a plasma process using a radio frequency power. Known as one kind of plasma processing apparatuses using such plasma process is a parallel plate type plasma processing apparatus. In this type of plasma processing apparatus, a semiconductor wafer is mounted on a lower electrode serving as a mounting table, and a plasma is generated by applying a radio frequency power between the lower electrode and an upper electrode facing the lower electrode. Then, various processes such as a film forming process, an etching process and the like are performed on the target substrate by the generated plasma.

In this plasma processing apparatus, the target substrate is attracted to and held on an electrostatic chuck (ESC) on the lower electrode. The electrostatic chuck includes a HV (High Voltage) electrode embedded in a dielectric. A DC power supply is connected to the HV electrode. As shown in FIG. 7 which describes a principle of the electrostatic chuck, if a high voltage is applied to the HV electrode 51, negative charges are charged in the target substrate W while positive charges are charged in the HV electrode 51, just like electric charges are charged in two opposite electrodes of a capacitor. The attraction of the target substrate W to the electrostatic chuck is realized by an attracting force between the negative and positive charges, that is, by a Coulomb force.

Besides the mentioned electrostatic chuck, there is also known a Johnsen-Rahbek type electrostatic chuck as illustrated in FIG. 8. This Johnsen-Rahbek electrostatic chuck is of a type which allows some electric current to flow by lowering a resistance of a dielectric. Though a Johnsen-Rahbek force is a basically Coulomb force, this term is used to refer to a case where a Coulomb force is exerted in a minute gap between the electrostatic chuck and the target substrate. In FIG. 8, a notation C1 denotes a capacity of the gap; R1, a contact resistance between the target substrate and the electrostatic chuck; C2, a capacity of the dielectric; and R2, a resistance of the dielectric. The attracting force is exerted between two electrodes of the capacitor C1.

In both of the two types of electrostatic chucks using the Coulomb force and the Johnsen-Rahbek force, residual charges accumulated in their dielectric layers may cause a problem as follows. If the residual charges are present, there would still remain an attracting force between the electrostatic chuck and the target substrate, which make it difficult to separate the target substrate from the electrostatic chuck after the plasma process.

In order to facilitate the separation of the target substrate, there is known a reverse application method of applying, to the HV electrode of the electrostatic chuck, a DC voltage of a reverse polarity to that of a DC voltage applied to attract the target substrate (see, for example, International Patent Publication No. 2004-021427, 1 to 7 lines on page 13). For example, in case a positive DC voltage is applied to the HV electrode for the attraction of the target substrate, a negative voltage is applied in a reverse application process after the plasma process whereby residual positive charges accumulated in the dielectric layer are moved to the DC power supply. Meanwhile, when a negative DC voltage is applied for the attraction of the target substrate, a positive DC voltage is applied to the HV electrode after the plasma process. In this way, by applying a DC voltage having a reverse polarity to that of the DC voltage applied to attract the target substrate, the residual charges accumulated in the dielectric layer can be extracted, so that the separation of the target substrate is facilitated.

However, there is an occasion that electric charges still remain even after the DC voltage of the reverse polarity is applied after the plasma processing. In such case, the separation of the target substrate from the electrostatic chuck may be difficult.

For example, if ceramic is used as the dielectric layer to obtain a heat resistance and the dielectric layer is heated to a high temperature, a volume resistivity decreases, so that it becomes difficult to eliminate the residual charges. Further, since the amount of electric charges accumulated in the dielectric layer increases with a lapse of time, the time required for the reverse application would also be increased. The increase of the time period for the reverse application results in a deterioration of throughput of the plasma processing apparatus.

### SUMMARY OF THE INVENTION

In view of the foregoing, the present invention provides a plasma processing method and apparatus capable of suppressing an accumulation of electric charges in a dielectric layer after a plasma process.

In accordance with a first aspect of the present invention, there is provided a plasma processing method for performing a plasma process on a target substrate by generating a plasma between an upper electrode and a lower electrode facing each other by means of applying a radio frequency power therebetween. The method includes: applying a DC voltage of a positive or negative polarity to an inner electrode of an electrostatic chuck on the lower electrode to attract and hold the target substrate thereon; and changing the positive or negative polarity of the DC voltage applied to the inner electrode of the electrostatic chuck to an opposite polarity thereto between a time when the application of the radio frequency power from the radio frequency power supply is started to perform the plasma process of the target substrate and a time when the plasma process is completed.

It is preferable that the polarity changing includes stopping the application of the radio frequency power from the radio frequency power supply and a supply of a thermally conductive gas between a bottom surface of the target substrate and a top surface of the electrostatic chuck prior to changing the polarity of the DC voltage; changing the polarity of the DC voltage applied to the inner electrode of the electrostatic chuck; and resuming the application of the radio frequency power from the radio frequency power supply and the supply of the thermally conductive gas between the bottom surface of the target substrate and the top surface of the electrostatic chuck.

It is also preferable that the polarity changing includes continuing the application of the radio frequency power from the radio frequency power supply and a supply of the thermally conductive gas between a bottom surface of the target substrate and a top surface of the electrostatic chuck while the polarity of the DC voltage applied to the inner electrode of the electrostatic chuck is changed.

Further, it is preferable that the plasma processing further includes applying the DC voltage of the positive or negative polarity or an opposite polarity thereto to the inner electrode of the electrostatic chuck after the application of the radio frequency power from the radio frequency power supply is completed.

It is also preferable that a time period taken to apply the DC voltage of the positive or negative polarity in the DC voltage application is longer than a time period taken to apply the DC voltage of the opposite polarity to the inner electrode of the electrostatic chuck in the polarity changing; and the DC voltage of the opposite polarity is also applied to the inner electrode of the electrostatic chuck in a reverse application process.

Further, it is preferable that the electrostatic chuck is formed of a dielectric material and the inner electrode is embedded in the dielectric material.

In accordance with a second aspect of the present invention, there is provided a plasma processing apparatus including: a radio frequency power supply for generating a plasma by applying a radio frequency power between an upper electrode and a lower electrode facing each other; a DC power supply for supplying a DC voltage of a positive or negative polarity to an inner electrode of an electrostatic chuck on the lower electrode to attract and hold a target substrate thereon; and a control unit for controlling the radio frequency power supply and the DC power supply, wherein the control unit changes the positive or negative polarity of the DC voltage applied to the inner electrode of the electrostatic chuck to an opposite polarity thereto between a time when the application of the radio frequency power from the radio frequency power supply is started to perform the plasma process of the target substrate and a time when the plasma process is completed.

Since the polarity of the DC voltage applied to the inner electrode of the electrostatic chuck is reversed during the plasma processing of the target substrate, it is possible to reduce the residual charges accumulated in the dielectric layer after the plasma processing.

### BRIEF DESCRIPTION OF THE DRAWINGS

The above and other features of the present invention will become apparent from the following description of an embodiment given in conjunction with the accompanying drawings, in which:

FIG. 1 provides a schematic configuration view of a plasma processing apparatus in accordance with an embodiment of the present invention;

FIG. 2 sets forth a schematic diagram showing a semiconductor wafer lifted by pusher pins;

FIG. 3 presents an exemplary timing chart of an etching process;

FIG. 4 offers an another exemplary timing chart of the etching process;

FIG. 5 depicts a still another exemplary timing chart of the etching process;

FIG. 6 provides a comparative example of a timing chart of the etching process;

FIG. 7 presents a diagram for describing a principle of an electrostatic chuck using a Coulomb force; and

FIG. 8 sets forth a diagram for describing a principle of an electrostatic chuck using a Johnsen-Rahbek force.

### DETAILED DESCRIPTION OF THE EMBODIMENT

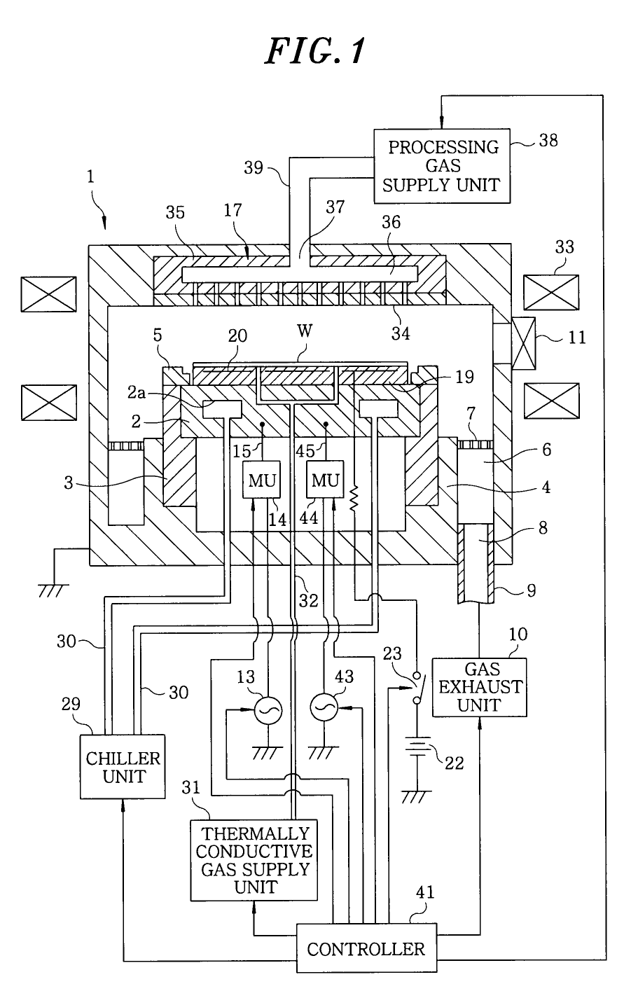

Hereinafter, a plasma processing apparatus in accordance with an embodiment of the present invention will be described with reference to the accompanying drawings which form a part hereof. FIG. 1 is a schematic view showing an overall configuration of a plasma processing apparatus (etching apparatus). In FIG. 1, reference numeral 1 denotes a cylindrical chamber 1 made of, for example, aluminum, stainless steel, or the like. The inside of the chamber 1 is capable of being sealed airtightly, and the chamber 1 is electrically grounded.

Disposed inside the chamber 1 is a disk-shaped susceptor 2 for mounting thereon, for example, a semiconductor wafer W as a target substrate to be processed. The susceptor 2 is made of a conductive material such as aluminum or the like, and it also serves as a lower electrode. The susceptor 2 is sustained by a cylindrical sustaining member 3 which is made of an insulating material such as ceramic. The cylindrical sustaining member 3 is supported by a cylindrical supporting member 4. Further, a focus ring 5 made of quartz or the like is disposed on a top surface of the cylindrical sustaining member 3 in a ring shape to surround the top surface of the susceptor 2.

An annular gas exhaust passageway 6 is formed between a sidewall of the chamber 1 and the cylindrical supporting member 4, and an annular baffle plate 7 is attached to an inlet or at a middle portion of the gas exhaust passageway 6. A gas exhaust port 8 is provided at a bottom portion of the gas exhaust passageway 6, and a gas exhaust unit 10 is connected to the gas exhaust port 8 via a gas exhaust line 9. The gas exhaust unit 10 includes a vacuum pump and serves to depressurize a processing space inside the chamber 1 to a specific vacuum degree. A gate valve 11 for opening or closing a loading/unloading port for the semiconductor wafer W is provided at a sidewall of the chamber 1.

A radio frequency power supply 13 for plasma generation is electrically connected to the susceptor 2 via a matching unit (MU) 14 and a power supply rod 15. The radio frequency power supply 13 supplies a radio frequency power of higher frequency (HF) of, for example, 40 MHz to the susceptor 2 serving as the lower electrode. Further, a shower head 17 serving as an upper electrode is installed at a ceiling portion of the chamber 1. By applying the radio frequency power from the radio frequency power supply 13 to the susceptor 2, plasma is generated between the susceptor 2 and the shower head 17.

Further, a bias radio frequency power supply 43 for attracting ions in the plasma toward the semiconductor wafer W is connected to the susceptor 2 via a matching unit (MU) 44 and a power supply rod 45. The radio frequency power supply 43 supplies a radio frequency power of a lower frequency (LF) of, for example, 12.88 MHz or 3.2 MHz, to the susceptor 2. Ions in the plasma are attracted onto the semiconductor wafer W by the radio frequency power in such a LF range.

Disposed on the top surface of the susceptor 2 is an electrostatic chuck 19 for maintaining the semiconductor wafer W thereon by an electrostatic attracting force. The electrostatic chuck 19 is made of a dielectric such as ceramic or the like. A HV (High voltage) electrode (inner electrode) 20, which is a conductor, is embedded in the electrostatic chuck 19.

A DC power supply 22 is electrically connected to the HV electrode 20 via a switch 23. The DC power supply 22 supplies a positive or negative voltage of, for example, 2500 V or 3000 V to the HV electrode 20. The switch 23 changes the positive or negative polarity of the DC voltage applied to the electrostatic chuck 19 from the DC power supply 22. If the DC voltage is applied to the HV electrode 20 from the DC power supply 22, the semiconductor wafer W is attracted to and held on the electrostatic chuck 19 by a Coulomb force. As for the electrostatic chuck 19, there are two types: a unipolar type and a bipolar type. Each of the unipolar type and the bipolar type can be divided into a Coulomb type and a Johnsen-Rahbek type again. In accordance with the present embodiment, any one of these four types can be used as the electrostatic chuck 19.

A coolant path 2a extending along, for example, a circumferential direction is provided inside the susceptor 2. A coolant of a specific temperature, for example, cooling water is circulated through the coolant path 2a from a chiller unit 29 via a coolant line 30. By controlling the temperature of the coolant, a processing temperature of the semiconductor wafer W on the electrostatic chuck 19 can be regulated.

A thermally conductive gas, for example, He gas is supplied between the top surface of the electrostatic chuck 19 and the bottom surface of the semiconductor wafer W from a thermally conductive gas supply source 31. When observed microscopically, the bottom surface of the semiconductor wafer W and the top surface of the electrostatic chuck 19 are not flat but uneven. Accordingly, a contact area between the semiconductor wafer W and the electrostatic chuck 19 is small. Thus, by supplying the thermally conductive gas between the bottom surface of the semiconductor wafer W and the electrostatic chuck 19, thermal conductivity between the semiconductor wafer W and the electrostatic chuck 19 can be improved.

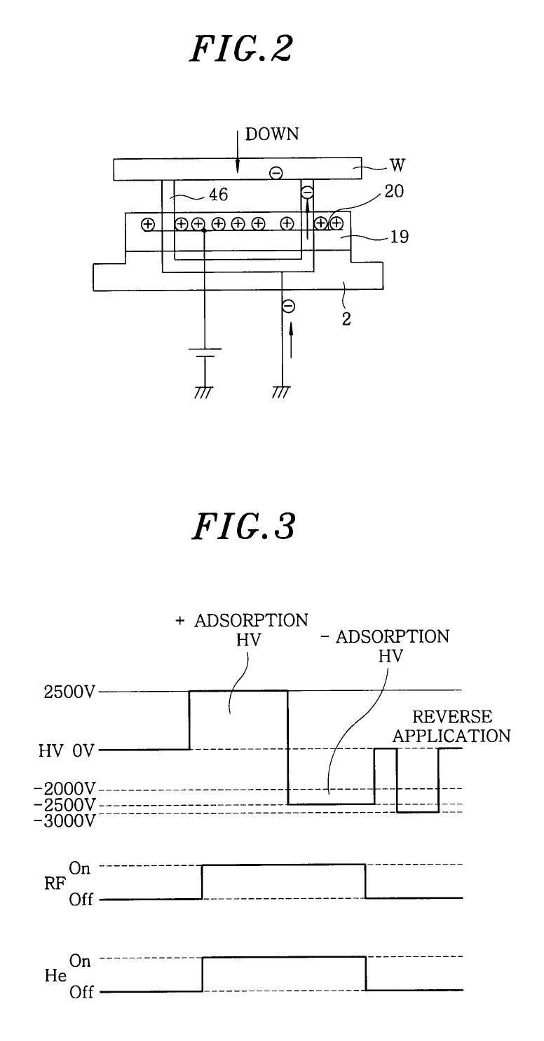

Provided inside the susceptor 2 are pusher pins 46, which are protruded above or retreated below the top surface of the electrostatic chuck 19 (see FIG. 2). To hold the semiconductor wafer W on the electrostatic chuck 19, the semiconductor wafer W is carried on the pusher pins 46 protruded above the top surface of the electrostatic chuck 19, and by lowering the pusher pins 46, the semiconductor wafer W is placed on the top surface of the electrostatic chuck 19. Meanwhile, to separate the semiconductor wafer W from the electrostatic chuck 19, the pusher pins 46 located below the top surface of the electrostatic chuck 19 is raised whereby the semiconductor wafer W is lifted from the top surface of the electrostatic chuck 19.

A shower head 17 disposed at a ceiling portion of the chamber 1 includes an electrode plate 34 forming a lower surface thereof and provided with a number of gas holes; and an electrode support 35 detachably holding the electrode plate 34. A buffer space 36 is provided inside the electrode support 35, and a gas supply line 39 from a processing gas supply unit 38 is connected to a gas inlet 38 of the buffer space 36.

The shower head 17 is arranged to face the susceptor 2 in parallel and is grounded. The shower head 17 and the susceptor 2 function as a pair of electrodes, i.e., an upper electrode and a lower electrode, respectively. A vertical radio frequency electric field is formed between a space between the shower head 17 and the susceptor 2 by a radio frequency power applied to the susceptor 2. Due to a radio frequency discharge, high-density plasma is generated around the surface of the susceptor 2.

Annular ring magnets 33 are concentrically disposed around the chamber 1. The ring magnets 33 form a magnetic field in the processing space between the susceptor 2 and the shower head 17. The ring magnets 33 are configured to be revolvable around the chamber 1 by a rotating mechanism.

A control unit 41 controls each constituent component of the plasma etching apparatus, for example, the gas exhaust unit 10, the radio frequency power supplies 13 and 43, the switch 23 for the electrostatic chuck, the chiller unit 29, the thermally conductive gas supply unit 31, the processing gas supply unit 38, and so forth.

Now, a sequence of an etching process, which is performed by using the etching apparatus configured as described above, will be explained.

First, the gate valve 11 provided at the chamber 1 is opened, and a semiconductor wafer W is loaded into the chamber 1 from a load lock chamber (not shown) disposed adjacent to the gate valve 11, and is mounted on the pusher pins 46 of the susceptor 2 by a transfer mechanism (not shown). After the transfer operation is completed, the transfer mechanism is retreated from the chamber 1. Thereafter, the loading/unloading port is closed by the gate valve 11, and the inside of the chamber 1 is evacuated to vacuum by the gas exhaust unit 10.

FIG. 3 provides a timing chart of the etching process. In FIG. 3, the horizontal axis represents time, while the vertical axis indicates a DC voltage applied to the HV electrode 20, an on/off operation of the radio frequency power supplies 13 and 43 and an on/off state of a He gas supplying operation.

After the semiconductor wafer W is loaded into the chamber 1, a DC voltage (HV) is applied to the HV electrode 20. As shown in FIG. 2, if a DC voltage of a positive polarity is applied to the HV electrode 20 while the pusher pins 46 are being raised, negative charges are charged in the semiconductor wafer W via the pusher pins 46. If the pusher pins 46 are lowered to thereby locate the semiconductor wafer W on the electrostatic chuck 19, the semiconductor wafer W is attracted to and held on the electrostatic chuck 19 by a Coulomb force.

After applying a positive DC voltage (HV) of, for example, 2500 to the HV electrode, an etching gas is supplied from the processing gas supply unit 38 into the chamber 1, and a radio frequency power of HF and a radio frequency power of LF are supplied to the susceptor 2 serving as the lower electrode from the radio frequency power supplies 13 and 43, respectively. As a result of supplying the radio frequency powers to the susceptor 2, a radio frequency electric filed is formed between the shower head 17 serving as the upper electrode and the susceptor 2 serving as the lower electrode, resulting in a generation of plasma. Simultaneously with the supply of the radio frequency powers to the susceptor 2, a thermally conductive gas such as He is supplied from the thermally conductive gas supply unit 31 between the bottom surface of the semiconductor wafer W and the top surface of the electrostatic chuck 19. In this state, the etching process of the semiconductor wafer W is started.

Between a time when the application of the radio frequency powers from the radio frequency power supplies 13 and 43 to the susceptor 2 is started and a time when the etching process is completed, the polarity of the DC voltage applied to the HV electrode 20 of the electrostatic chuck 19 is reversed to positive. That is, the application of the DC voltage of, for example, +2500 V is stopped, and a DC voltage of, for example, −2500 V is applied to the HV electrode 20 of the electrostatic chuck 19 during the etching process. As long as an attracting force by the Coulomb force can be obtained, the negative DC voltage value may be identical with or different from the positive DC voltage value. If the polarity of the HV electrode 20 of the electrostatic chuck 19 is reversed, residual charges accumulated in the dielectric layer are removed during the etching process.

In accordance with the present embodiment, the supply of the thermally conductive gas between the bottom surface of the semiconductor wafer W and the top surface of the electrostatic chuck 19 and the application of the radio frequency powers from the radio frequency power supplies 13 and 43 are continued while the polarity of the DC voltage applied to the HV electrode 20 of the electrostatic chuck 19 is changed. Since the voltage level of the HV electrode 20 becomes zero instantaneously at a moment when the polarity of the DC voltage applied to the HV electrode 20 is changed, there is a concern that the attracting force for the semiconductor wafer W may be reduced at that moment. However, a self-bias voltage is applied to the semiconductor wafer W during plasma generation, which also generates an attracting force is still generated. Thus, even while the polarity of the DC voltage to the HV electrode 20 is changed, it hardly occurs that the semiconductor wafer W is deviated from the electrostatic chuck 19.

If a preset processing time elapses or an end point of the etching process is detected, the control unit 41 makes a determination that the etching process is terminated, and stops the supply of the radio frequency powers from the radio frequency power supplies 13 and 43. Simultaneously, the supply of the thermally conductive gas from the thermally conductive gas supply unit 31 is also stopped. For example, when an oxide film is etched, atoms different from those of the oxide film will appear in the chamber 1 if the etching of the oxide film progresses to the extent that a film under the oxide film is exposed. In such case, by detecting a plasma emission, an end point of the etching process can be detected.

After the application of the radio frequency powers from the radio frequency power supplies 13 and 43 is finished, that is, after the etching process is completed, the application of the negative DC voltage to the HV electrode 20 of the electrostatic chuck 19 is temporarily stopped. Thereafter, a DC voltage of a negative polarity (reverse to the polarity of the positive DC voltage applied for the attraction of the semiconductor wafer W) is applied. To reduce a processing time for this reverse application, the DC voltage of the reverse application is set to have an absolute value larger than that of the DC voltage applied during the etching process, for example, it is set to be −3000V. This reverse application of the DC voltage is carried out to reduce the amount of residual charges accumulated in the dielectric layer. The time period of the reverse application of the DC voltage is determined by the magnitude or application time of the positive DC voltage and the negative DC voltage applied to the HV electrode 20 of the electrostatic chuck 19. In accordance with the present embodiment, since the polarity of the DC voltage applied to the HV electrode 20 of the electrostatic chuck 19 is changed, the residual charges in the dielectric layer can be removed during the etching process as well. Accordingly, the time period taken for the reverse application after the etching process can be shortened.

Theoretically, it is also possible to reverse the positive or negative polarity during the etching process to neutralize the residual charges in the dielectric layer. In such case, it may be possible to omit the reverse application process after the etching process. In a realistic point of view, however, this is impossible due to unstable parameters. Further, to cope with a change in the magnitude or application time of the DC voltage, the reverse application process is necessary. In the event that the magnitude of the negative DC voltage applied during the etching process is great or the application time thereof is lengthened, the polarity of the reverse application may become positive.

After the reverse application of the negative DC voltage to the HV electrode 20 of the electrostatic chuck 19 is stopped, the semiconductor wafer W is lifted from the top surface of the electrostatic chuck 19 by the pusher pins 46. The semiconductor wafer W lifted by the pusher pins 46 is unloaded from the chamber 1 by the transfer mechanism.

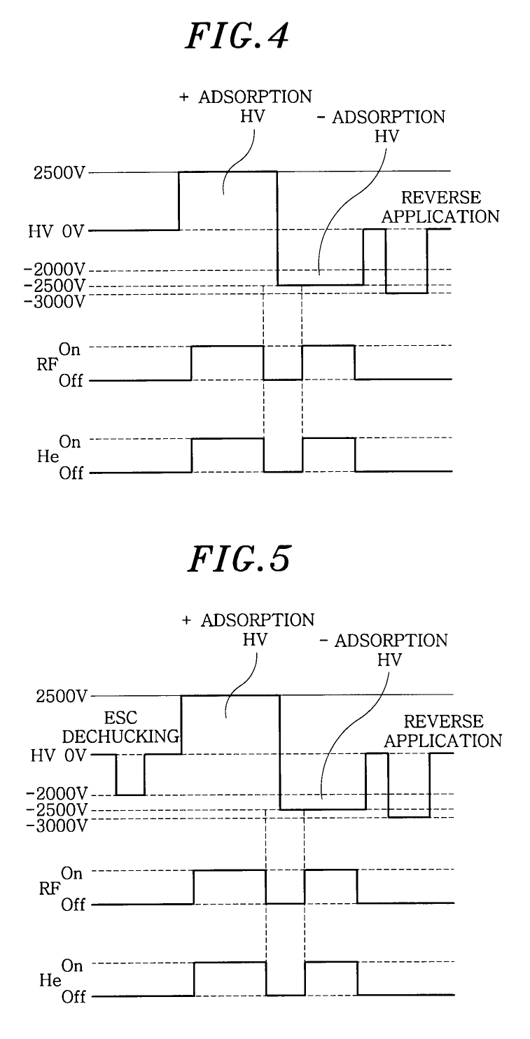

FIG. 4 presents another exemplary timing chart of the etching process. In this example, the etching process is temporarily stopped when the polarity of the DC voltage applied to the HV electrode 20 of the electrostatic chuck 19 is changed from positive to negative. That is, prior to changing the polarity of the DC voltage, the application of the radio frequency powers from the radio frequency powers 13 and 43 and the supply of the thermally conductive gas from the thermally conductive gas supply unit 31 are stopped temporarily. Then, the polarity of the DC voltage applied to the HV electrode 20 is changed from positive to negative, and, afterwards, the application of the radio frequency powers from the radio frequency power supplies 13 and 43 and the supply of the thermally conductive gas from the thermally conductive gas supply unit 31 are resumed at the same time. As described above, even when the polarity of the DC voltage applied to the HV electrode 20 of the electrostatic chuck 19 is changed during the etching process, the semiconductor wafer W is unlikely to be separated from the electrostatic chuck 19. In this embodiment, to prevent the separation of the semiconductor wafer W from the electrostatic chuck 19 more securely, the etching process is temporarily stopped when the polarity of the DC voltage to the HV electrode 20 is changed. In such case, however, a total etching time may be increased.

FIG. 5 provides still another exemplary timing chart of the etching process. In this example, an ESC dechucking process of applying a negative DC voltage to the HV electrode 20 is conducted before a next semiconductor wafer W is held on the electrostatic chuck 19. The other processes than the ESC dechuking process are identical with those described in FIG. 4.

### TEST EXAMPLE

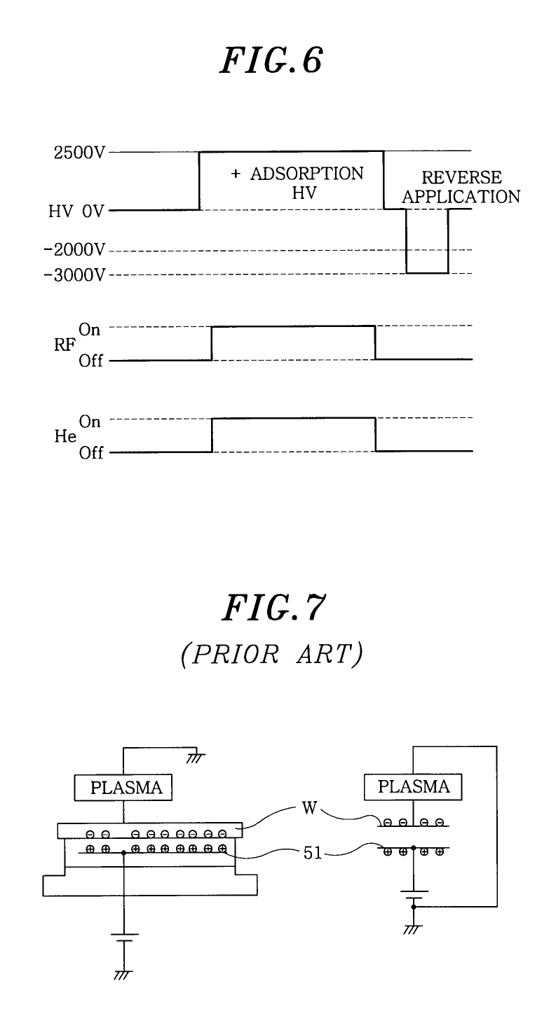

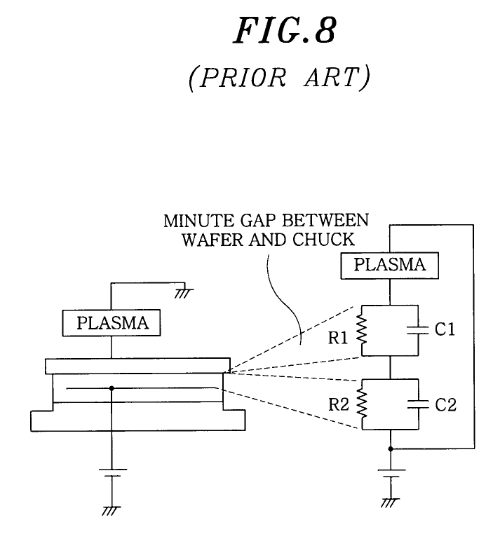

An etching process was performed in accordance with the timing chart provided in FIG. 3, and a time period required for a reverse application was measured. As a comparative example, an etching process was conducted in accordance with a timing chart of FIG. 6 without performing a polarity change, and a time period required for a reverse application was measured.

Table 1 shows the results.

TABLE 1

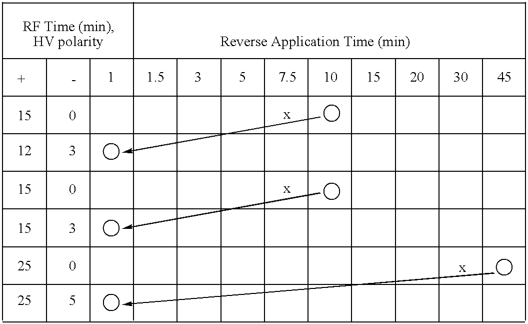

Numbers in “+” column of Table 1 represent time (min) during which a positive DC voltage is applied to the HV electrode 20, while numbers in “−” column of Table 1 represent time (min) during which a negative voltage is applied to the HV electrode 20. The sum of the time in the “+” column and the time in the “−” column is a total RF time (radio frequency power application time).

A reverse application time is a time period during which a reverse application is carried out on the HV electrode 20. In Table 1, notations O and x indicate whether the semiconductor wafer W could be smoothly separated from the electrostatic chuck 19 without popping or jumping up when the pusher pins 46 lifts the semiconductor wafer W. O denotes that smooth separation was possible, while x denotes that smooth separation was impossible. If the reverse application time is insufficient, residual charges would be left, causing the semiconductor wafer W to pop when it is lifted by the pusher pins 46.

As indicated in the first line of Table 1, when a positive DC voltage was applied to the HV electrode 20 for 15 minutes without applying a negative DC voltage (i.e., when the polarity change of the DC voltage is not carried out as in the comparative example shown in FIG. 6), 10 minutes was required for the reverse application. In contrast, when the positive DC voltage was applied to the HV electrode 20 for 12 minutes and a negative DC voltage was applied to the HV electrode 20 for next 3 minutes by changing the polarity of the DC voltage, as described in the second line of Table 1, the reverse application time could be reduced to 1 minute.

Further, as shown in the fourth line of Table 1, when a positive DC voltage was applied to the HV electrode 20 for 15 and a negative DC voltage was applied to the HV electrode 20 for next 3 minutes by changing the polarity of the DC voltage, the reverse application time could be reduced to 1 minute. At this time, the RF time amounts to 18 minutes (15 minutes+3 minutes), which is slightly longer than that in the case when no negative DC voltage was applied. However, if the total time after the loading of the semiconductor wafer W into the chamber till the unloading thereof is considered, the reverse application time is added to the RF time. Thus, the total time can be reduced from 25 minutes (15 minutes+10 minutes) to 19 minutes (18 minutes+1 minute).

The last line and the second last line of Table 1 provide a comparison of cases where the RF time was set to be 25 minutes or longer. When no polarity change of a DC voltage is performed, a reverse application time of 45 minutes was required when a RF time was set to be 25 minutes. In contrast, if a polarity change is carried out and a negative DC voltage is applied to the HV electrode 20 for 5 minutes, a reverse application time could be extremely reduced to 1 minute.

In the above, the plasma etching apparatus in accordance with the embodiment of the present invention has been described. However, it is to be noted that the present invention is not limited to the embodiment but may be modified in various ways.

In the above-described plasma processing apparatus as shown in FIG. 1, though the dual radio frequency powers of two different frequencies (HF and LF) are applied to the susceptor 2 serving as the lower electrode, it is also possible to apply a single-frequency power to the lower electrode or to apply a LF radio frequency power to the lower electrode while applying a HF radio frequency power to the upper electrode.

Moreover, in the above-described plasma processing apparatus, a radio frequency power for plasma generation is supplied to the susceptor after the DC voltage is applied to the HV electrode of the electrostatic chuck, and after stopping the supply of the radio frequency power for plasma generation, the application of the DC voltage to the HV electrode is stopped. However, it is also possible to supply a weak radio frequency power of a lower frequency than that of the radio frequency power for plasma generation from the radio frequency power supply while the DC power supply starts or stops the application of the DC voltage to the HV electrode. Furthermore, it is also possible to supply the weak radio frequency power to the susceptor from the radio frequency power supply while the DC power supply is applying a reverse voltage to the HV electrode.

Further, the present invention can also be applied to various types of plasma processing apparatuses such as a plasma CVD apparatus, a plasma oxidation apparatus, a plasma nitriding apparatus, a sputtering apparatus and the like.

Moreover, a target substrate of the present invention is not limited to the semiconductor wafer, and can be a LCD (Liquid Crystal Display) substrate, a photomask, a CD substrate, a printed circuit board or the like.

While the invention has been shown and described with respect to the embodiment, it will be understood by those skilled in the art that various changes and modifications may be made without departing from the scope of the invention as defined in the following claims.

What is claimed is:

1. A plasma processing method for performing a plasma process on a target substrate by generating a plasma between an upper electrode and a lower electrode facing each other by means of applying a radio frequency power therebetween, the method comprising:
applying a DC voltage of a positive or negative polarity to an inner electrode of an electrostatic chuck on the lower electrode to attract and hold the target substrate thereon; and
changing the positive or negative polarity of the DC voltage applied to the inner electrode of the electrostatic chuck to an opposite polarity thereto between a time when the application of the radio frequency power from the radio frequency power supply is started to perform the plasma process of the target substrate and a time when the plasma process is completed.

2. The plasma processing method of claim 1, wherein the polarity changing comprises:
stopping the application of the radio frequency power from the radio frequency power supply and a supply of a thermally conductive gas between a bottom surface of the target substrate and a top surface of the electrostatic chuck prior to changing the polarity of the DC voltage;
changing the polarity of the DC voltage applied to the inner electrode of the electrostatic chuck; and
resuming the application of the radio frequency power from the radio frequency power supply and the supply of the thermally conductive gas between the bottom surface of the target substrate and the top surface of the electrostatic chuck.

3. The plasma processing method of claim 1, wherein the polarity changing comprises:
continuing the application of the radio frequency power from the radio frequency power supply and a supply of the thermally conductive gas between a bottom surface of the target substrate and a top surface of the electrostatic chuck while the polarity of the DC voltage applied to the inner electrode of the electrostatic chuck is changed.

4. The plasma processing method of claim 1, further comprises:
applying the DC voltage of the positive or negative polarity or an opposite polarity thereto to the inner electrode of the electrostatic chuck after the application of the radio frequency power from the radio frequency power supply is completed.

5. The plasma processing method of claim 1, wherein a time period taken to apply the DC voltage of the positive or negative polarity in the DC voltage application is longer than a time period taken to apply the DC voltage of the opposite polarity to the inner electrode of the electrostatic chuck in the polarity changing; and the DC voltage of the opposite polarity is also applied to the inner electrode of the electrostatic chuck in a reverse application process.

6. The plasma processing method of claim 1, wherein the electrostatic chuck is formed of a dielectric material and the inner electrode is embedded in the dielectric material.

7. A plasma processing apparatus comprising:
a radio frequency power supply for generating a plasma by applying a radio frequency power between an upper electrode and a lower electrode facing each other;
a DC power supply for supplying a DC voltage of a positive or negative polarity to an inner electrode of an electrostatic chuck on the lower electrode to attract and hold a target substrate thereon; and
a control unit for controlling the radio frequency power supply and the DC power supply,
wherein the control unit changes the positive or negative polarity of the DC voltage applied to the inner electrode of the electrostatic chuck to an opposite polarity thereto between a time when the application of the radio frequency power from the radio frequency power supply is started to perform the plasma process of the target substrate and a time when the plasma process is completed.
